(19) United States
(12) Patent Application Publication
(10) Pub. No.: US 2002/0118008 A1
(43) Pub. Date: Aug. 29, 2002

(54) Autohandler

(76) Inventors: Kenji Takagi, Tokyo (JP); Shinwu Go, Tokyo (JP)

Correspondence Address: FLYNN, THIEL, BOUTELL & TANIS, P.C., 2026 Rambling Road, Kalamazoo, MI, 49008-1699, US

(21) Appl. No.: 10/079,653

(22) Filed: Feb. 20, 2002

(30) Foreign Application Priority Data
Feb. 27, 2001 (JP) 2001-52620

(51) Int. Cl. G01R 31/02

(52) U.S. Cl. 324/158.1

(57) ABSTRACT

There is provided an autohandler for bringing terminals of an IC into pressure contact with contacts of an IC socket IC socket securely, capable of applying an appropriate contact force to the IC, and capable of regulating the contact force so as to cope with different types of IC with ease. The autohandler provided with transport means for moving the IC to bring the terminals of the IC into pressure contact with contacts of an IC socket so as to test the IC, said autohandler comprising a damper intervened between the transport means and the IC and having an airtight space therein, a pressure gauge for measuring an internal pressure of the airtight space, and a controller for controlling a transport stop position of the IC so that a value measured by the pressure gauge becomes a prescribed value.

### TECHNICAL FIELD OF THE INVENITON

The invention relates to an autohandler of an IC test system, particularly to a contact mechanism with pressure (hereinafter referred to as pressure contacting mechanism) of ICs applied to a horizontal conveyance system autohandler for selecting surface mounting type package ICs using an IC socket.

### BACKGROUND OF THE INVENTION

FIG. 5 shows a construction of the main portion of a conventional autohandler. In FIG. 5, depicted by 10 is transport means, 11 is holding means, 20 is an IC, 30 is an IC socket, 101 is a cylinder, 102 is a piston, 110 is pressure regulating means, and 120 is control means.

Among these components, the cylinder 101 is held by the transport means 10. The piston 102 forming an airtight space S is movably inserted into the cylinder 101. The holding means 11 for holding the IC 20 is provided at the end of the piston 102. The pressure regulating means 110 is connected to the airtight space S inside the cylinder 101, and it comprises, for example, a pressure reducing valve and an air source for regulating the internal pressure of the airtight space S at a constant value.

By use of the autohandler having the foregoing construction, terminals 21 are allowed to be conductive with contacts 31 by transporting (lowering) the IC 20 by the transport means 10 so that the terminals 21 of the IC 20 are brought into pressure contact with the contacts 31 provided in the IC socket 30, thereby testing the IC 20. A distance (stroke) of the IC 20 to be lowered for allowing the terminals 21 to be conductive with the contacts 31 is set in advance at an appropriate value to the extent that the terminals 21 are brought into contact with the contacts 31 under pressure (hereinafter referred to as terminals are pressure contact with the contacts 31) so that control means 120 controls the transport means 10 to lower the transport means 10 by a set stroke.

The transport means 10 lowers the IC 20 via the airtight space S. Accordingly, the internal pressure of the airtight space S is maintained to be equal to an appropriate contact force by the pressure regulating means 110, and when the cylinder 101 is lowered lower than the point where the terminals 21 contact the contacts 31, the terminals 21 of the IC 20 are brought into pressure contact with the contacts 31 under appropriate contact force.

However, with the conventional autohandler, even if the terminals 21 of the IC 20 are not brought into pressure contact with the contacts 31 owing to the inferior accuracy of the respective components or erroneous setting of the stroke, there is a problem that the reliability of the testing apparatus is lowered because of the lack of the detecting function. Further, under aging phenomena of the contacts 31, there occurs a case where the originally set stroke can not suffice a contact force, and hence the stroke has to be periodically reset or the IC socket 30 has to be replaced with another one.

Further, if various types of ICs 20 are tested, it is necessary to change strokes depending on the sizes and the shapes of the ICs 20 to be tested. Further, if the number of terminals is varied, appropriate contact forces are varied, resulting in the change of the components such as the pressure regulating means 110, the cylinder 101, the piston 102 and the like so as to change the internal pressure of the airtight space S, so that it took much time and labor every time the types of ICs 20 to be tested are changed.

Further, the contact force to be applied to the IC 20 is decided by a pressure receiving area of the cylinder 101, (piston 102), it is necessary to replace the cylinder 101 and the piston 102 with those having a large pressure receiving area, or the driving force of the transport means 10 is directly transferred to the IC 20 without the intervention of the cylinder 101 and piston 102. If the driving force of the transport means 10 is directly transferred to the IC 20 to regulate the contact force, there is no means other than the regulation of the stroke so that process of trail and error has to be repeated for deciding the stroke capable of applying an appropriate contact force to the IC 20. Even if the stroke is decided in such a manner, there is a case that an appropriate contact force can not be applied to the IC 20 owing to the aging phenomena of the contacts 31, the shapes and accuracy of the respective components of the respective ICs.

### SUMMARY OF THE INVENTION

The invention has been developed in view of the foregoing problems of the conventional autohandler, and it is an object of the invention to provide an autohandler enabling the terminals of an IC to bring into pressure contact with contacts reliably, capable of applying an appropriate contact force, capable of coping with different types of IC tests with ease, and capable of regulating the contact force with ease.

To achieve the above object, the autohandler provided with transport means 10 for moving an IC 20 to bring terminals 21 of the IC 20 into pressure contact with contacts 31 of an IC socket 30 so as to test the IC 20 according to the first aspect of the invention is characterized in comprising a damper 40 intervened between the transport means 10 and the IC 20 and having an airtight space S therein, a pressure gauge 50 for measuring an internal pressure of the airtight space S, and a controller 60 for controlling a transport stop position of the IC 20 so that a value measured by the pressure gauge 50 becomes a prescribed value.

The autohandler according to the second aspect of the invention is characterized in further comprising pressure compensation means 70 for maintaining a steady internal pressure of the airtight space S at a fixed value based on the value measured by the pressure gauge 50.

The autohandler according to the third aspect of the invention is characterized in further comprising pressure regulating means 80 for setting a steady internal pressure of the airtight space S at a value in response to changes in types of the IC 20.

The autohandler according to the fourth aspect of the invention is characterized in further comprising storage means 90 for storing a transport stop position of the IC 20 when the IC 20 is first tested, and wherein the controller 60 stops the IC 20 at the transport stop position stored in the storage means 90 during subsequent testing of the IC 20.

The autohandler according to the fifth aspect of the invention is characterized in that the damper 40 comprises a cylinder 41 fixed to the transport means 10, and a piston 42 fixed to holding means for holding the IC 20 and inserted into the cylinder 41 to be slidable freely therein to form the airtight space S.

### BRIEF DESCRIPTION OF THE DRAWINGS

FIG. 1 is a block diagram showing the construction of a main portion of an autohandler according to a preferred embodiment of the invention.

FIG. 2 is a view showing the construction of a main portion of an autohandler according to the preferred embodiment of the invention.

FIG. 3 is a view for explaining the operation of the autohandler according to the preferred embodiment of the invention.

FIG. 4 is an enlarged view showing the construction of the autohandler according to the preferred embodiment of the invention.

FIG. 5 is a view showing the construction of a main portion of a conventional autohandler.

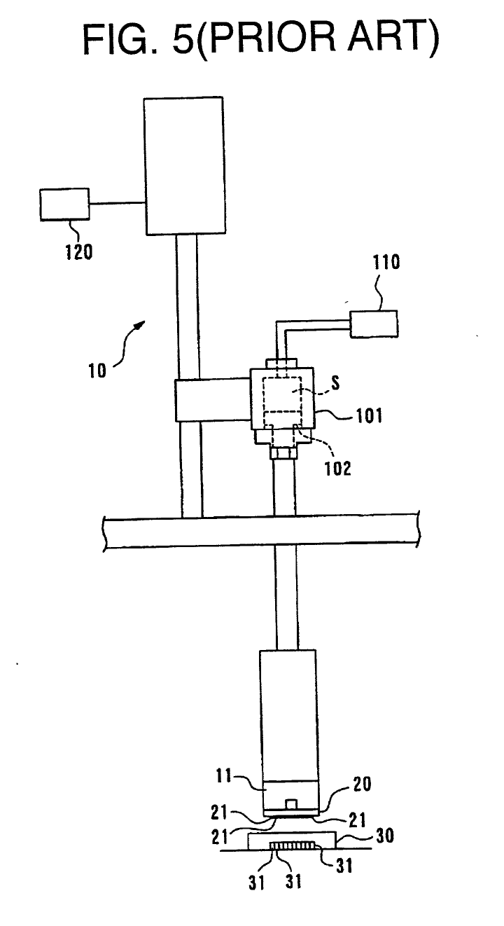

### PREFERED EMBODIMENTS OF THE INVENITON

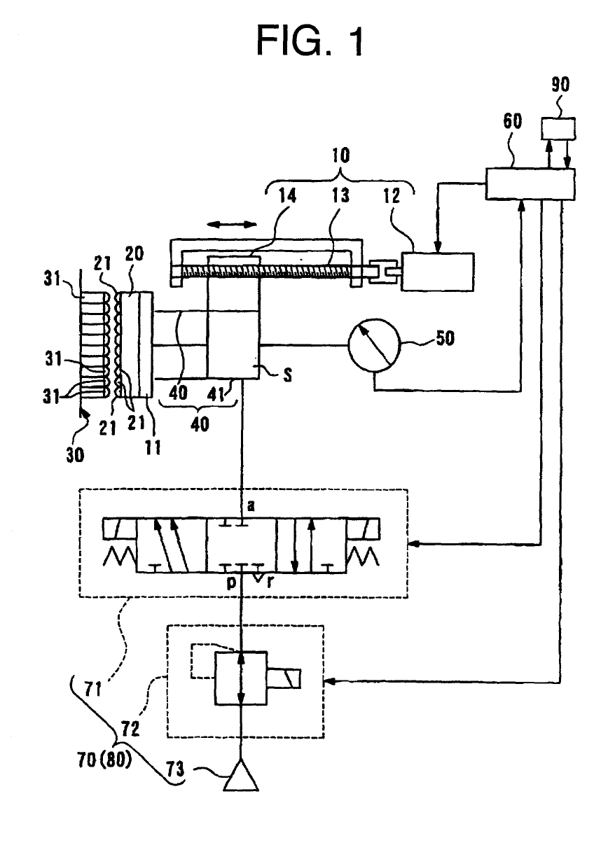

A preferred embodiment of the autohandler according to the invention is now described to with reference to FIG. 1 to FIG. 4.

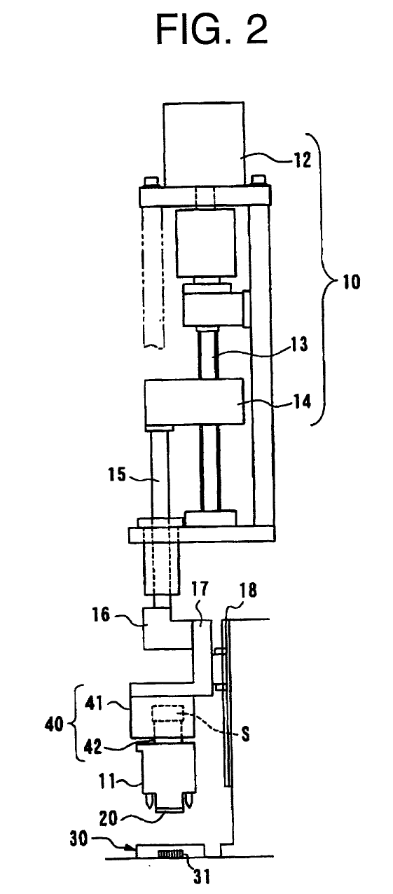

FIG. 1 is a block diagram showing the construction of a main portion of an autohandler according to a preferred embodiment of the invention. In FIG. 1, depicted by 10 is transport means, 20 is an IC, 30 is an IC socket, 40 is a damper, 50 is a pressure gauge, 60 is a controller, 70 is a pressure compensation means, 80 is pressure regulating means and 90 is storage means. FIG. 2 is a view showing the construction of a main portion of the autohandler.

The transport means 10 comprises a servomotor 12, a ball screw 13 which is turned by the servomotor 12, and a direct advancing member 14 coupled to the ball screw 13. The number of revolutions of servomotor 12 is controlled by the controller 60.

The IC 20 is a so-called ball grid array wherein the terminals 21 are arrayed on the surface of the IC 20 in vertical and lateral directions. Multiple contacts 31 are arrayed on the IC socket 30 corresponding to the positions of the terminals 21. The terminals 21 are conductive with an IC tester (not shown) via the contacts 31.

As shown in FIG. 2, the damper 40 comprises a cylinder 41 and a piston 42. The cylinder 41 is fixed to the direct advancing member 14 of the transport means 10 via a push rod 15, a block 16 and a base angle 17, and it is transported together with the direct advancing member 14. The base angle 17 is slidably coupled to a guide rail 18, and the cylinder 41 is transported with excellent accuracy when the base angle 17 is slid along the guide rail 18.

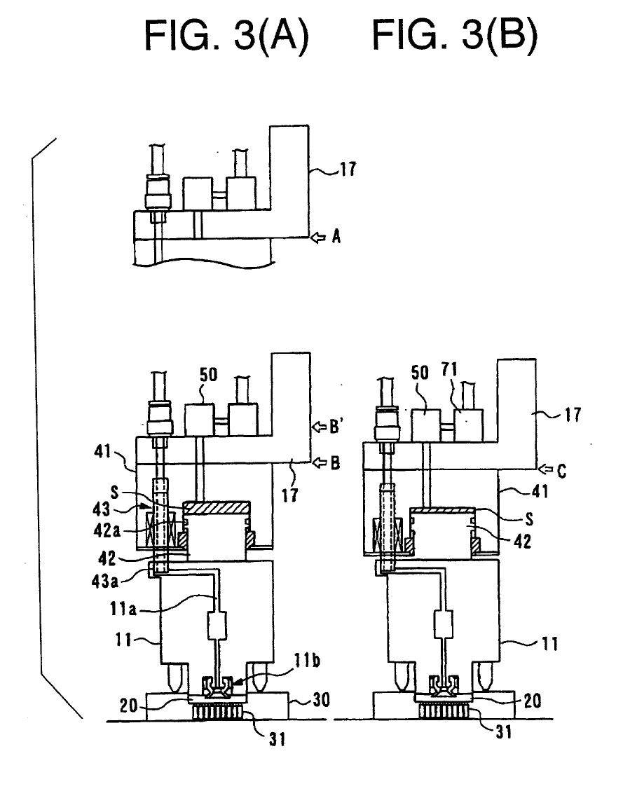

As shown in FIG. 3(A), the piston 42 is slidably inserted into the cylinder 41 to form an airtight space S between the piston 42 and cylinder 41 by a seal member 42a of the piston 42 provided on the circumferential surface. A bearing 43 built in the cylinder 41 is slidably coupled with a guide rod 43a provided on the holding means 11 so that the piston 42 can move up and down with excellent accuracy.

The holding means 11 for holding the IC 20 is fixed to the underside of the piston 42. The holding means 11 has a suction pad 11b coupled to an air source (not shown) via the cylinder 41, and a suction path 11a provided inside the guide rod 43a. The suction pad 11b sucks and holds the IC 20 by a suction force of the air source.

Returning back to FIG. 1, the pressure gauge 50 is of an electric control type for measuring an internal pressure of the airtight space S and electrically outputting pressure values measured thereby (hereinafter referred to as measured value). The measured value is inputted to the controller 60.

The controller 60 controls, upon reception of the measured value of the pressure gauge 50, the number of revolution of the servomotor 12 and the operation of the pressure compensation means 70 in response to the measured value.

The pressure compensation means 70 comprises a solenoid valve 71, a pressure reducing valve 72, and an air source 73, and compensates the internal pressure of the airtight space S. The solenoid valve 71 is formed of a five port closed center connection type, wherein a port a connected to the airtight space S, a port p connected to the air source 73 via the pressure reducing valve 72 and a discharge port r are used. The solenoid valve 71 is controlled in operation by the controller 60 to supply air from the air source 73 to the airtight space S or to discharge the air inside the airtight space S.

A steady internal pressure (an internal pressure of the airtight space S in a no load state) P0 is maintained to a fixed value by the controller 60 and pressure compensation means 70. For example, if the internal pressure of the airtight space S is lowered, e.g. when air is leaked outside from the airtight space S, the solenoid valve 71 is driven by the controller 60 so that air is supplied to the airtight space S to increase the internal pressure of the airtight space S. On the other hand, if the internal pressure of the airtight space S is excessively increased, the solenoid valve 71 is driven by the controller 60 to discharge the air inside the airtight space S through the discharge port r so that the internal pressure of the airtight space S can be lowered. Meanwhile, although the pressure compensation means 70 is coupled with the airtight space S along a path which path is different from the path along which the pressure gauge 50 provided in FIG. 1, the pressure gauge 50 and the pressure compensation means 70 may be connected to each other in series along a single path as shown in FIG. 3.

The pressure regulating means 80 can regulate the internal pressure of the airtight space S by use of the solenoid valve 71, the pressure reducing valve 72 and the air source 73 of the pressure compensation means 70. That is, the internal pressure of the airtight space S can be arbitrarily regulated when the pressure reducing valve 72 and the solenoid valve 71 of the respective electric control type are controlled by the controller 60.

The storage means 90 is provided in the controller 60 and can store the number of the revolutions of the servomotor 12. The controller 60 rotates the servomotor 12 in response to the stored number of revolutions of the servomotor 12.

The operation of the autohandler of the invention is now described. The operation of the cylinder 41 which is transported by the transport means 10 is first explained with reference to FIG. 3(A) and FIG. 3(B). The cylinder 41 is stopped at an original position A where the IC 20 which is not yet measured is positioned over the IC socket 30 (the upper portion in FIG. 3(A)). Then, the cylinder 41 is lowered to a contact position B where the terminals 21 are brought into pressure contact with the contacts 31 (preliminary lowering step, FIG. 3(A)). The cylinder 41 is further lowered to allow the terminals 21 to be brought into pressure contact with the contacts 31 and stopped at a transport stop position C where the terminals 21 are brought into pressure contact with the contacts 31 at the appropriate measuring pressure P1 (pressure contact step, FIG. 3(B)).

The controller 60 for controlling the operation of the cylinder 41 (driving of the transport means 10) is described next. The controller 60 regulates the internal pressure of the airtight space S to the steady pressure P0 in advance by the pressure compensation means 70, then closes the ports of the solenoid valve 71 and starts the preliminary lowering step. Since the preliminary lowering step is an operation allowing the IC 20 to approach to the contacts 31, the faster the speed is, the shorter the cycle time of the autohandler is.

When the terminals 21 are brought into pressure contact with the contacts 31, the measured value of the pressure gauge 50 starts to increase so that the controller 60 detects that the cylinder 41 arrives the contact position B, and the routine moves to a pressure contact step. In the pressure contact step, the controller 60 drives the servomotor 12 with a given number of pulses per unit, i.e., feeds the servomotor 12 by pitch control (pitch feeding) so as to lower the cylinder 41 at low speed, and decides whether or not the measured value of the pressure gauge 50 arrives the measuring pressure P1 every time the servomotor 12 is driven with one pitch, and repeats the pitch feeding until the measured value reaches the measuring pressure P1. When the measured value of the pressure gauge 50 arrives the measuring pressure P1, the controller 60 stops the lowering of the cylinder 41 and starts the test of the IC 20.

The controller 60 allows the storage means 90 to store a proper stop position B′ (a safe position where the IC 20 does not collide with the contacts 31) over the contact position B in advance, then the controller 60 transports the cylinder 41 from the original position A to the stop position B′ at a stoke, wherein the cylinder 41 is stopped at the stop position B′, then the routine may move to the pressure contact step while the terminals 21 do not contact the contacts 31. As a result, the transport time is shortened without damaging the IC 20, thereby shortening the cycle time.

Further, the transport stop position C in the initial operation test of the IC 20 to be tested is stored in the storage means 90, and the IC 20 is stopped by the controller 60 at the transport stop position C when subsequently testing the IC 20, thereby shortening the cycle time.

The setting of the measuring pressure P1 is described next. When the terminals 21 of the IC 20 are brought into pressure contact with the contacts 31 so that the internal pressure of the airtight space S becomes P, the following expression is established for a contact force F applied to the IC 20.

F=(P×u×η+M×g) (1)

where M is mass of the piston 42 and that of the holding means 11 under the piston 42, η is a transfer efficiency of the force owing to air pressure, u is a pressure receiving area of the piston 42 and g is acceleration of gravity.

Meanwhile, a recommendable contact force f of the terminals 21 of the IC 20 per piece is fixed. The following expression is established for an ideal contact force F0 applied to the IC 20 based on the recommendable contact force f and the number N of the terminals 21.

F0=f×N (2)

Accordingly, the following expression is established for a measuring pressure P1 for applying the ideal contact force F0 to the IC 20 from the expressions (1) and (2)

P1=(f×N−M×g)/u×η (3)

Accordingly, the appropriate measuring pressure P1 to be applied to the respective ICs 20 can be calculated from the expression (3). Further, the calculation can be executed by the controller 60, and if the mass M, the pressure receiving area u, transmission efficiency η are respectively inputted in advance, the appropriate measured value P1 can be set in the controller 60 merely by inputting the recommendable contact force f and the number N of the terminals 21 which are respectively selected when operating the autohandler.

The steady internal pressure P0 is described next. Although the steady internal pressure P0 is generally equal to the atmosphere pressure in a normal environment, a repulsive force obtained by compressing the airtight space S is limited so that there occurs a case where the steady internal pressure P0 cannot cope with the IC 20 to be tested if it is type for requiring a large contact force. Accordingly, the steady internal pressure P0 is set at a value higher than the atmosphere pressure while the repulsive force obtained by compressing the airtight space S is made large so that the pressure contact force between the IC 20 and the contacts 31 can be made larger. The steady internal pressure P0 can be regulated by the pressure regulating means 80.

The terminals 21 may be brought into pressure contact with the contacts 31 by increasing the internal pressure of the airtight space S to the measuring pressure P1 by use of the pressure regulating means 80 without driving the servomotor 12 in a pressure contact step while the terminals 21 are not brought into pressure contact with the contacts 31 by lowering the cylinder 41, as set forth above.

Further, when air is supplied to the airtight space S by use of the pressure regulating means 80 while the cylinder 41 is lowered to a position under the contact position B, thereby increasing the internal pressure of the airtight space S so that the terminals 21 can be brought into pressure contact with the contacts 31 with a larger force. This function can be applied to a case where air inside the airtight space S is leaked through the seal member 42a by the operation of the piston 42 and the like so that the internal pressure of the airtight space S can not be increased to the measuring pressure P1.

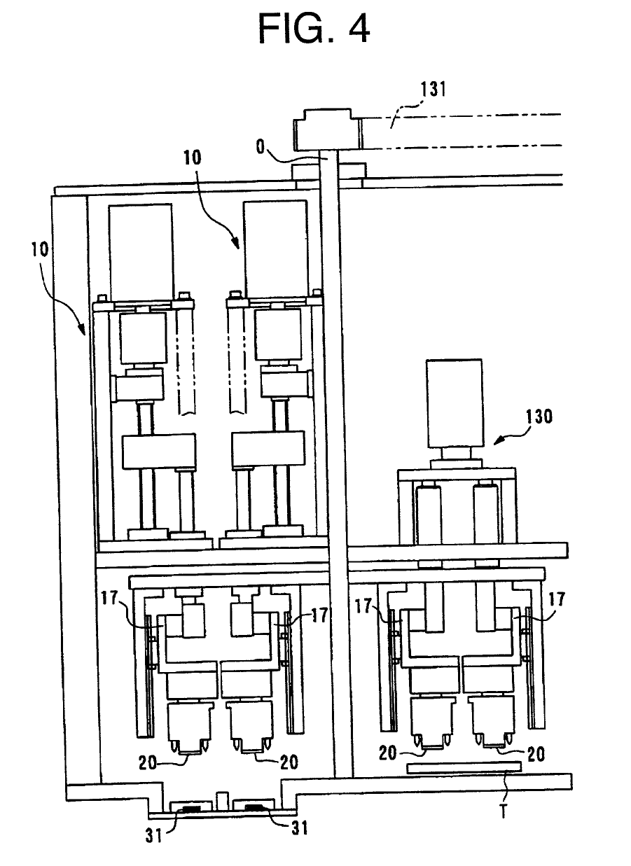

FIG. 4 is a view enlarging the construction shown in FIG. 2. In FIG. 4, the base angle 17, the damper 40 and the servomotor 12 respectively shown in FIG. 2 are arranged with line symmetry about a rotation axis O. There are two sets of the base angle 17, damper 40 and servomotor 12 while one set is formed of a pair of components. It is possible to arrange these components one by one, or one set is formed of not less than two components and four set can be arranged at an interval of 90° on the circumference of the rotation axis O.

The rotation axis O is rotated by a timing belt 131 for rotating the base angle 17, the damper 40 and the holding means 11. When the base angle 17 is moved to the left side in FIG. 4, it is connected to the block 16 of the transport means 10, and the autohandler effects the foregoing operations to test the IC 20. The base angle 17, the damper 40 and the holding means 11 which are moved to the right side in FIG. 4 are respectively connected to a vertically movable mechanism 130 so that the IC 20 which is not yet measured is sucked and held by a tray T while the IC 20 which has been already tested is placed on the tray T, thereby carrying in or out the IC 20. In such a manner, the ICs 20 can be continuously tested according to the autohandler of the invention.

As mentioned in detail above, according to the preferred embodiment of the invention, the airtight space S is intervened between the transport means 10 and the IC 20, and the transport means 10 is driven while measuring the internal pressure of the airtight space S and also the transport stop position C of the IC 20 is controlled by the controller 60 so that the measured value becomes the measuring pressure P1, thereby enabling the IC 20 to bring into pressure contact with the contacts 31 securely at an appropriate contact force.

Although the configurations and combinations of the respective components shown in the preferred embodiment of the invention are mere example, and they can be changed variously based on designing requirement and the like in the scope without departing from the gist of the invention. Although the damper 40 is formed of the cylinder 41 and the piston 42, thereby forming the airtight space S, in which air is sealed, there may be employed a construction, for example, using a balloon in which air is sealed so as to prevent air from being leaked outside, or using high viscosity fluid which is hardly leaked outside compared with air to be sealed in the airtight space S. Still further, although a BGA type package is exemplified as the IC according to the preferred embodiment of the invention, the invention can be applied to other surface mounting type IC.

As mentioned in detail above, according to the preferred embodiment of the invention, the airtight space is intervened between the transport means and the IC, the transport means is driven while measuring the internal pressure of the airtight space and the transport stop position of the IC is controlled by the controller so that the measured value becomes the measuring pressure, thereby enabling the IC 20 to bring into pressure contact with the contacts 31 securely at an appropriate contact force, resulting in the realization of a high reliable testing.

Further, since the steady pressure of the airtight space can be maintained at a given value based on the measure value of the pressure gage, a pressure can be compensated even in the case where air is leaked from the airtight space, or the pressure is excessively increased, so that the set contact force can be produced securely.

Still further, since the steady internal pressure of the airtight space can be regulated with ease, the autohandler can cope with various types of ICs with ease without taking time and labor for replacing the parts and the like.

Yet, since the transport stop position, when the IC is first tested, is stored, and the IC can be stopped at the stored transport stop position in the subsequent testing of the IC so that the transport time of the IC can be shortened every time the IC is tested, thereby realizing the reduction of the operation cost.

Further, since the airtight space is formed by the cylinder and the piston, the autohandler having excellent maintenance property can be realized.

What is claimed is:

1. An autohandler provided with transport means for moving an IC to bring terminals of the IC into pressure contact with contacts of an IC socket so as to test the IC, said autohandler comprising:
a damper intervened between the transport means and the IC and having an airtight space therein;
a pressure gauge for measuring an internal pressure of the airtight space; and
a controller for controlling a transport stop position of the IC so that a value measured by the pressure gauge becomes a prescribed value.

2. The autohandler according to claim 1, further comprising pressure compensation means for maintaining a steady internal pressure of the airtight space at a fixed value based on the value measured by the pressure gauge.

3. The autohandler according to claim 1 or 2, further comprising pressure regulating means for setting a steady internal pressure of the airtight space at a value in response to changes in types of the IC.

4. The autohandler according to any of claims 1 to 3, further comprising storage means for storing a transport stop position of the IC when the IC is first tested, and wherein the controller stops the IC at the transport stop position stored in the storage means during subsequent testing of the IC.

5. The autohandler according to claim 1, wherein the damper comprises a cylinder fixed to the transport means, and a piston fixed to holding means for holding the IC and inserted into the cylinder to be slidable freely therein to form the airtight space.
